(19) United States
(12) Patent Application Publication
(10) Pub. No.: US 2006/0022344 A1
(43) Pub. Date: Feb. 2, 2006

(54) Semiconductor device capable of preventing chemical damage and method for fabricating the same

(76) Inventors: Sung-Kwon Lee, Kyoungki-do (KR); Tae-Woo Jung, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/143,139

(22) Filed: Jun. 1, 2005

(30) Foreign Application Priority Data
Jul. 29, 2004 (KR) 2004-0059533

(51) Int. Cl. H01L 23/52

(52) U.S. Cl. 257/758

(57) ABSTRACT

Disclosed are a semiconductor device with a three-dimensional storage node and a method for fabricating the same. The semiconductor device includes: an inter-layer insulation layer formed on a substrate; a first plug contacted to the substrate by penetrating into the inter-layer insulation layer; an insulation layer formed on the first plug; a second plug contacted to the first plug by penetrating into the insulation layer and projected in an upward direction from a surface level of the insulation layer; a barrier layer formed on the second plug and the insulation layer; and a storage node formed on the second plug to be connected with the second plug through a portion where the barrier layer is removed.

### FIELD OF THE INVENTION

The present invention relates to a method for fabricating a semiconductor device; and more particularly, to a semiconductor device with a three-dimensional storage node and a method for fabricating the same.

### DESCRIPTION OF RELATED ARTS

As the cell size of a semiconductor device has been finer, there have been a lot of efforts in many different ways to secure a required electric charge storage capacitance. One of the efforts is to form a capacitor in a three-dimensional structure. A cylinder type is a typical example of the capacitor formed in the three-dimensional structure.

FIG. 1 is a top view illustrating a plurality of conventional storage nodes of capacitors.

Referring to FIG. 1, a plurality of bit lines 10 are arranged in one direction, and a plurality of plugs 11 for storage node contacts are arranged between the bit lines 10 in the form of matrix. There are a plurality of storage nodes 12 being overlapped with the corresponding plugs 11 and contacting the plugs 11.

Meanwhile, a sacrificial layer for forming a capacitor is generally etched by using a mask pattern with a rectangular shape or an elliptical shape having a large ratio of a long axis to a short axis, which originally has a square shape but provides an elliptical etch profile because of a characteristic of an adopted etch process, so that the plurality of cylinder type storage nodes 12 are formed. In this case, however, there may be a problem of an electric short between the storage nodes 12 because of leaning storage nodes 12 resulted from an interfacial tension created by the use of a solution of buffered oxide etchant (BOE) or hydrogen fluoride (HF) in a wet dip-out process.

As the scale of integration has been increased, the leaning phenomenon of the storage nodes 12 becomes more severe. That is, the leaning phenomenon becomes more severe as a distance D between the storage nodes 12 is decreased; the size of the storage node 12 is increased; the width of the storage node 12 is decreased; and the height of the storage node 12 is increased.

Accordingly, one attempt to secure the effective area of the storage nodes 12 as large as possible and help the storage nodes 12 maintain a sufficient electrical connection with the plugs 11 is to arrange the storage nodes 12 in the form of zigzags.

That is, unlike the above described conventional matrix-like arrangement of the bottom electrodes 10 of the cylinder type capacitors, another arrangement is suggested to prevent the electric short between bottom electrodes caused by the interfacial tension during the wet dip-out process. That is, a pair of bottom electrodes disposed in opposite with a bit line between the bottom electrodes is arranged in the form of zigzags to thereby reduce a shard area between the paired electrodes. As a result of the reduction, it is possible to prevent the electric short between the bottom electrodes.

FIG. 2 is a top view illustrating an improved conventional semiconductor device with a plurality of bottom electrodes.

As shown in FIG. 2, a plurality of bit lines 20 are formed in a direction of an X axis. There are a plurality of imaginary lines of the X axis X1 and X2 practically pointing to the same direction of the X axis and a plurality of imaginary lines of a Y axis Y1 and Y2 practically perpendicular to the plurality of imaginary lines of the X axis. Herein, the X1 and the X2 denote a first imaginary line of the X axis and a second imaginary line of the X axis, respectively. Also, the Y1 and Y2 denote a fist imaginary line of the Y axis and a second imaginary line of the Y axis, respectively.

The first and the second imaginary lines of the X axis X1 and X2 and the first and the second imaginary lines of the Y axis Y1 and Y2 make a plurality of crisscross points O in the form of matrix or lattice. Also, a plurality of contact plugs 21 for storage nodes are arranged in the form of matrix. Particularly, a central point of each contact plugs 21 is positioned at the respective crisscross point O.

In more detail, the plurality of contact plugs 21 for the storage nodes are respectively connected with a plurality of cell contact plugs in contact with active regions of a substrate. In the first and the second imaginary lines of the Y axis Y1 and Y2, the plurality of contact plugs 21 are arranged with a first predetermined distance D1 corresponding to a width of the bit line 20 and in the first and the second imaginary lines of the X axis X1 and X2, the plurality of contact plugs 21 are arranged with a second determined distance D2.

Also, on top of the contact plugs 21, a plurality of bottom electrodes 22 are arranged with a third predetermined distance D3 in the first and the second imaginary lines of the X axis X1 and X2 to make electric contacts with the corresponding contact plugs 21.

Herein, a pair of a left first bottom electrode 22A and a left second bottom electrode 22B has the central point O1 positioned at the same first imaginary line of the Y axis Y1. The central point O1′ of the left second bottom electrode 22B and the central point O1″ of the left first bottom electrode 22A are positioned at different imaginary lines of the Y axis, i.e., a first shifted imaginary line Y1′ and a second shifted imaginary line Y1″, respectively. This different allocation of the central points O1′ and O1″ indicates that the pair of the left first bottom electrodes 22A and the left second bottom electrode 22B are arranged in the form of zigzags.

As described above, as the bottom electrodes 22 are arranged in the form of zigzags, the interfacial tension caused by a wet solution used when the sacrificial insulation layer (not shown) is removed through the wet dip-out process after the bottom electrodes 22 are formed can be more or less removed. Accordingly, it is possible to prevent the problem of the electric short between the bottom electrodes 22.

FIG. 3 is a cross-sectional view taken along of a line A-A′ as shown in FIG. 2.

Referring to FIG. 3, a first inter-layer insulation layer 31 is formed on a substrate 30. A cell contact plug 32 contacted to an impurity diffusion region (not shown) of the substrate 30 by penetrating into the first inter-layer insulation layer 31 and planarized at the same level as an upper portion of the first inter-layer insulation layer 31 is formed. A second inter-layer insulation layer 32 is formed on the cell contact plug 32 and the first inter-layer insulation layer 31. Although not illustrated, a plurality of bit lines (B/L) are electrically connected with a group of the cell contact plugs 32 by penetrating into the second inter-layer insulation layer 32. Each of the bit lines (B/L) includes a conductive layer 34, a hard mask 35 and spacers 36.

A third inter-layer insulation layer 37 is formed on the bit line (B/L), and a contact plug 38 for a storage node contacted to the cell contact plug 32 by penetrating into the third inter-layer insulation layer 37 and planarized at the same level as an upper portion of the third inter-layer insulation layer 37 is formed.

A contact pad 40 serving a role in helping the storage node be arranged in the form of zigzags is formed on the contact plug 38. The contact pad 40 is planarized at the same level as an upper portion of a fourth inter-layer insulation layer 39.

An etch stop layer 41 is formed on the contact pad 40 and the fourth inter-layer insulation layer 39. The etch stop layer 41 serves roles in preventing a bottom structure from being damaged during a dip-out process performed to remove a capacitor sacrificial layer for forming a cylinder type storage node and during etching the capacitor sacrificial layer. A storage node 42 is formed on a portion where the contact pad 40 is exposed by etching the etch stop layer 41. It should be noted that there are a number of the storage nodes 42 although one of the storage node 42 is shown in FIG. 3.

Meanwhile, in case the storage nodes 42 are arranged in the form of zigzags, the interfacial tension can be relatively released. However, during the formation of the storage node 42, if an overlap margin lacks, there may be a damage 43 to the bottom structure.

FIGS. 4A to 4C and FIGS. 5A and 5B are micrographs of scanning electron microscopy (SEM) illustrating defects generated when TiN is used as a storage node.

FIGS. 4A and 4B are micrographs illustrating each different region after TiN is deposited as the storage node and then, an annealing process is performed. FIG. 4C is a cross-sectional view taken along of a line I-I′ as shown in FIGS. 4A and 4B. It should be noted that a bunker type defect as denoted with X is generated.

FIGS. 5A and 5B are photographs illustrating each different region after TiN is deposited as the storage node and then, an annealing is not performed. These micrographs also show a bunker type defect as denoted with Y.

### SUMMARY OF THE INVENTION

It is, therefore, an object of the present invention to provide a semiconductor device capable of preventing an electric short between a plurality of storage nodes caused by the leaning and lifting storage nodes; sufficiently securing an electric charge storage capacitance by increasing an effective area; and preventing a bottom structure from being damaged by a wet dip-out process and a method for fabricating the same.

In accordance with one aspect of the present invention, there is provided a semiconductor device, including: an inter-layer insulation layer formed on a substrate; a first plug contacted to the substrate by penetrating into the inter-layer insulation layer; an insulation layer formed on the first plug; a second plug contacted to the first plug by penetrating into the insulation layer and projected in an upward direction from a surface level of the insulation layer; a barrier layer formed on the second plug and the insulation layer; and a storage node formed on the second plug to be connected with the second plug through a portion where the barrier layer is removed.

In accordance with another aspect of the present invention, there is provided a method for forming a semiconductor device, including the steps of: forming an inter-layer insulation layer on a substrate; forming a first plug contacted to the substrate by penetrating into the inter-layer insulation layer; sequentially forming a first insulation layer and a second insulation layer on the first plug; selectively etching the first insulation layer and the second insulation layer to form a contact hole exposing the first plug; forming a second plug contacted to the first plug through the contact hole and planarized at the same level as the second insulation layer; removing the second insulation layer, thereby causing the second plug to be projected from a surface of the first insulation layer; forming a barrier layer over the projected second plug; forming a sacrificial insulation layer on the barrier layer; selectively etching the sacrificial insulation layer and the barrier layer to form an opening exposing the second plug; forming a conductive layer over the opening; performing a planarization process until the sacrificial insulation layer is exposed, thereby forming an isolated storage node; and selectively removing the sacrificial insulation layer through a dip-out process.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a top view illustrating a plurality of conventional storage nodes of capacitors;

FIG. 2 is a top view illustrating a conventional semiconductor device with a plurality of improved bottom electrodes;

FIG. 3 is a cross-sectional view taken along a line A-A′ shown in FIG. 2;

FIGS. 4A to 4C and FIGS. 5A to 5B are micrographs of scanning electron microscopy (SEM) illustrating defects generated when TiN is used as a storage node;

FIG. 6 is a cross-sectional view illustrating a semiconductor device with a cylinder type storage node in accordance with the present invention; and

FIGS. 7A to 7E are cross-sectional views illustrating a process for forming a storage node of a capacitor in accordance with the present invention.

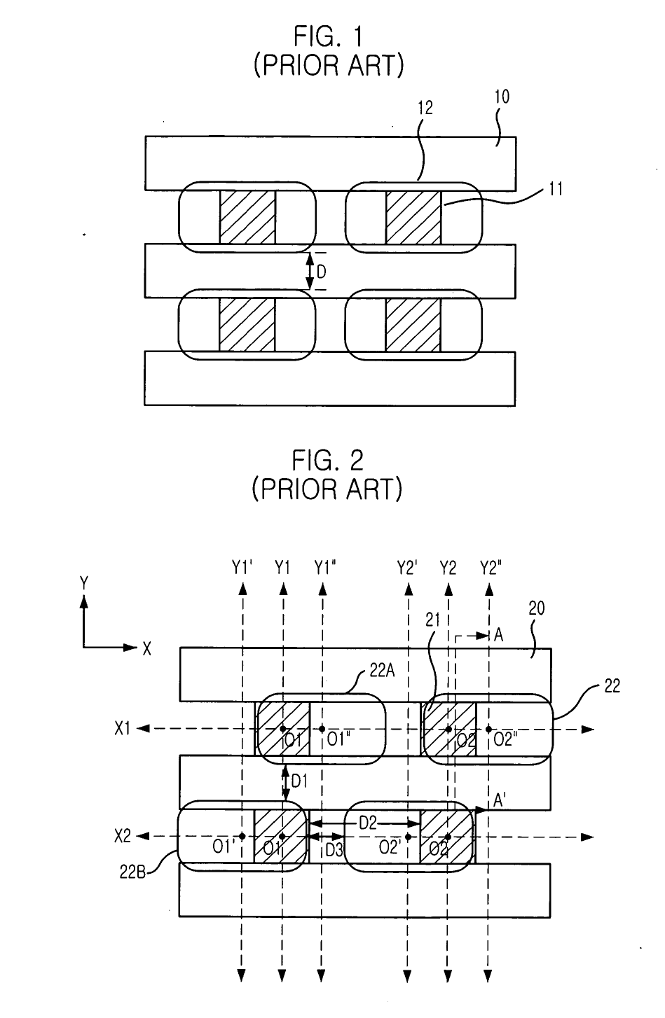

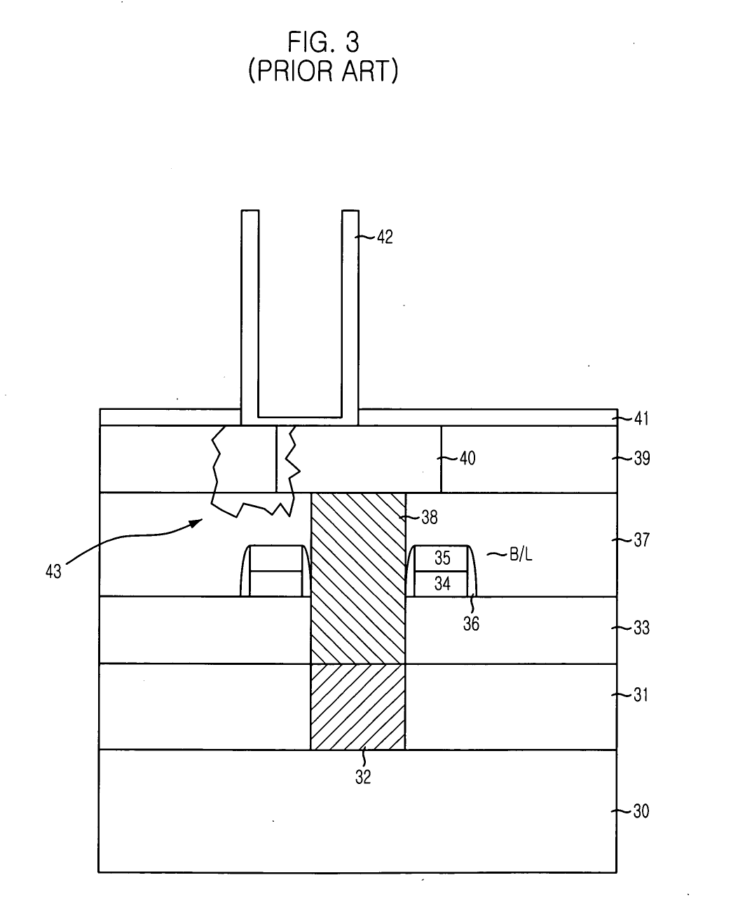

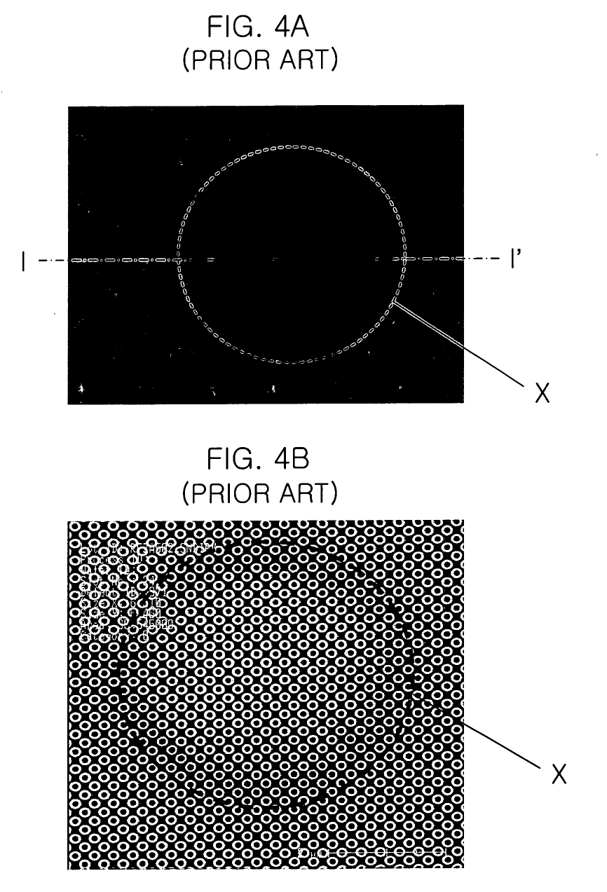

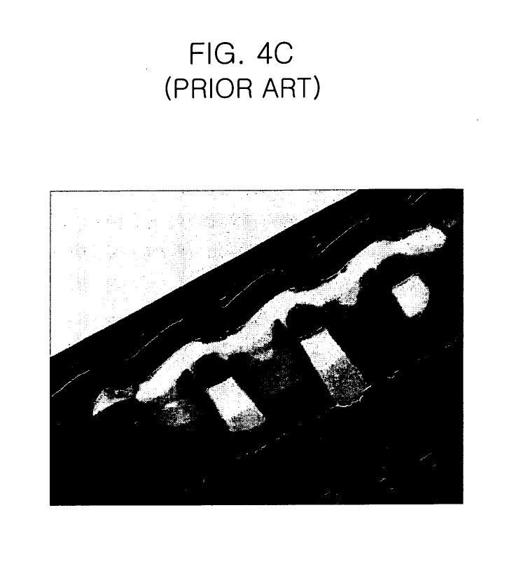

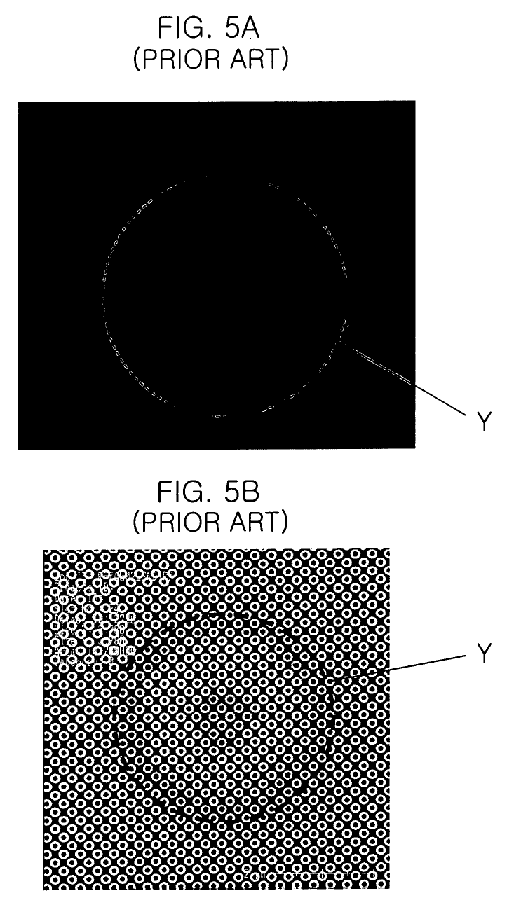

### DETAILED DESCRIPTION OF THE INVENTION

Hereinafter, detailed descriptions of preferred embodiments of the present invention will be provided with reference to the accompanying drawings.

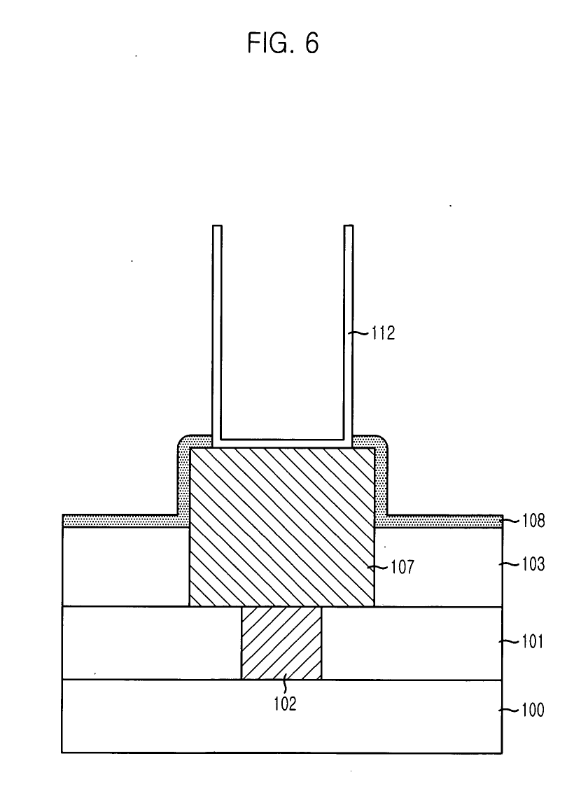

FIG. 6 is a cross-sectional view illustrating a semiconductor device with a cylinder type storage node in accordance with the present invention.

As shown, an impurity diffusion region (not shown) such as a source/drain region is formed on a substrate 100. The impurity diffusion region is formed to be aligned with a lateral side of a gate electrode (not shown). A cell contact plug 102 penetrates into an inter-layer insulation layer 101, thereby being in contact with the impurity diffusion region. An upper portion of the cell contact plug 102 is planarized at the same level as the inter-layer insulation layer 101.

An insulation layer 103 is formed on the cell contact plug 102 and the inter-layer insulation layer 101, and a contact plug 107 for forming a storage node connected with the cell contact plug 102 by penetrating into the insulation layer 103 is also formed on the cell contact plug 102.

The contact plug 107 for forming the storage node is projected in the upward direction from a surface level of the insulation layer 103.

Meanwhile, although not illustrated, another inter-layer insulation layer exists between the insulation layer 103 and the cell contact plug 102. A bit line electrically connected with another cell contact plug 102 by penetrating into said another inter-layer insulation layer is formed. However, detailed explanations about the bit line and the inter-layer insulation layer are omitted. A contact hole forming the contact plug 107 is aligned with a lateral side of the bit line.

A cylinder type storage node 112 is formed on the contact plug 107. The contact plug 107 that is not contacted to the storage node 112 is protected by barrier layer 108. The barrier layer 108 serves a role in preventing a bottom portion of the storage node 112 from being chemically damaged during a dip-out process performed to produce the cylinder type storage node 112 even though a mis-alignment arises during a photolithography process performed to form the storage node 112.

Herein, the barrier layer 108 is preferable formed by using a nitride-based insulation material. The inter-layer insulation layer 101 and the insulation layer 103 includes an oxide-based insulation layer such as a high density plasma (HDP) oxide layer, a borophosphosilicate glass (BPSG) layer or an oxide layer obtained through a plasma enhanced chemical vapor deposition (PECVD) method.

The cell contact plug 102 and the contact plug 107 are formed by using a material selected alone or in combination from a group consisting of a silicon layer using polysilicon and amorphous silicon, tungsten and titanium nitride (TiN).

Herein, the storage node 112 is formed by using a material selected from a group consisting of polysilicon, titanium nitride (TiN), tantalum (Ta), tantalum nitride (TaN), iridium (Ir), iridium oxide (IrO₂), ruthenium (Ru), ruthenium oxide (RuO₂), platinum (Pt) and a combination thereof.

Also, another barrier layer formed by using a material selected from a group consisting of Ti, TiN, Ta, TaN and titanium silicide (TiSi₂) and a combination thereof is formed at an interface between the storage node 112 and the contact plug 107. Furthermore, a conductive adhesion layer can be formed between the contact plug 107 and the aforementioned barrier layer formed at the interface.

A process for forming the cylinder type storage node of the capacitor with the above described structure will be explained hereinafter.

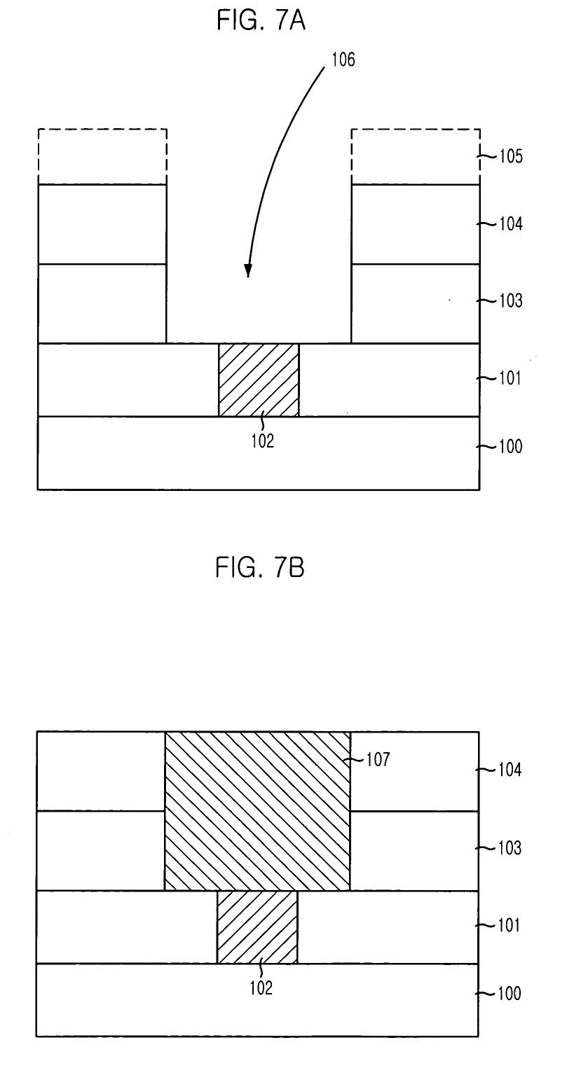

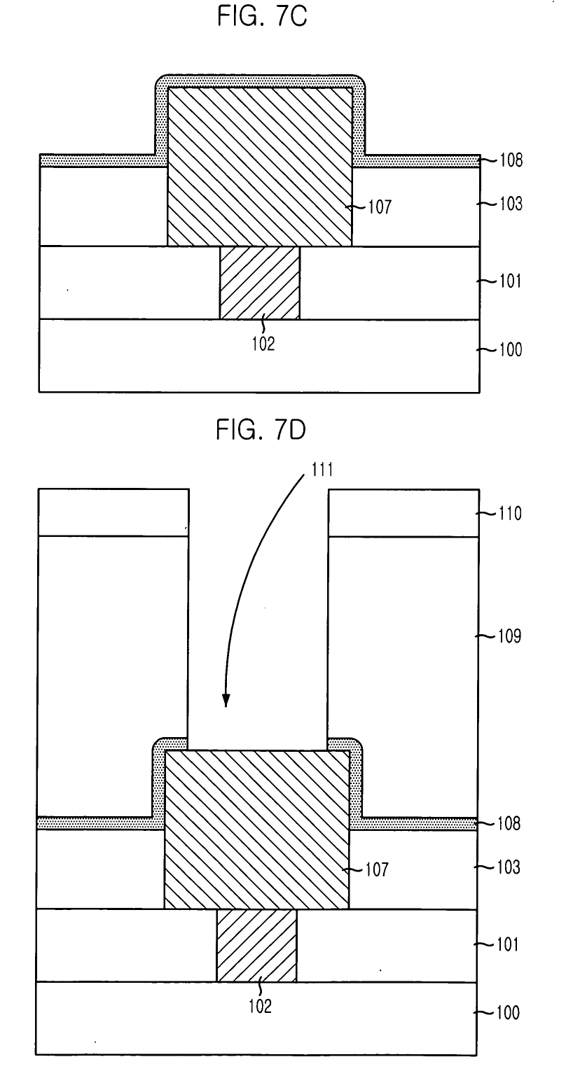

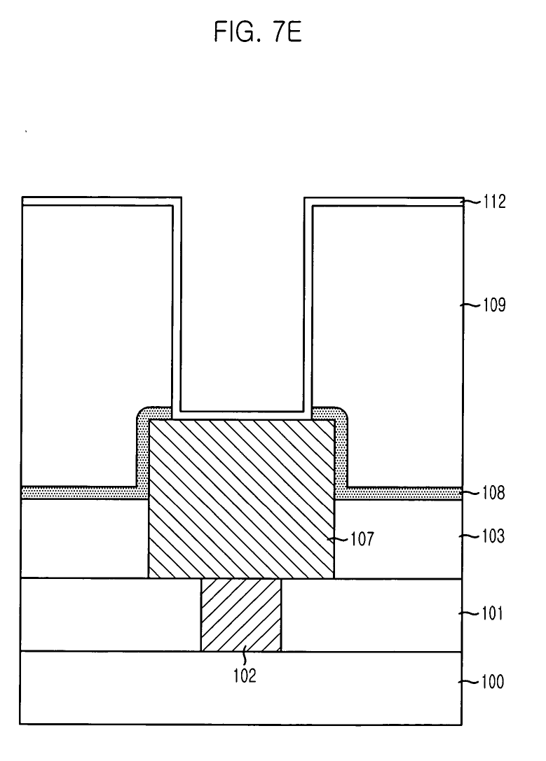

FIGS. 7A to 7E are cross-sectional views illustrating a process for forming a storage node of a capacitor in accordance with the present invention. Herein, the same reference numerals are used for the same configuration elements described in FIG. 6.

First, as shown in FIG. 7A, an inter-layer insulation layer 101 is formed on a substrate 100 provided with various elements such as transistors. Afterwards, a cell contact plug 102 being in contact with the substrate 100 by penetrating into the inter-layer insulation layer 101 is formed. The cell contact plug 102 is electrically connected to an impurity diffusion region of the substrate 100.

Herein, the inter-layer insulation layer 101 is typically made of tetraethylorthosilicate (TEOS) glass, and the cell contact plug 102 is made of a material selected in single or in combination from a group consisting of a silicon layer using polysilicon and amorphous silicon, tungsten and TiN.

Typically, a barrier layer formed by stacking Ti, TiSi₂ and TiN, or Ti and TiN is included on the cell contact plug 102 for the purposes of preventing formation of an ohmic contact and diffusion of a bottom electrode material into the substrate 100.

In addition to the TEOS, the inter-layer insulation layer 101 is formed by using one selected singly or in combination from a group consisting of a BPSG layer, an oxide layer obtained through a PECVD method, a borosilicate glass (BSG) layer, a phosphosilicateglass (PSG) layer, a HDP oxide layer, a spin-on-glass (SOG) layer and an advanced planarization layer (APL).

Subsequently, a bit line forming process is performed. However, an explanation about the bit line forming process is omitted.

Next, a nitride-based etch stop layer (not shown) is thinly formed along the above obtained profile including the bit line.

The etch stop layer serves a role in preventing a loss of the bit line during a subsequent etching process for forming a contact hole for a storage node. Particularly, a nitride-based material, e.g., silicon nitride or silicon oxynitride, is used to obtain an etch selectivity with respect to the oxide-based inter-layer insulation layer 101.

Next, a first insulation layer 103 and a second insulation layer 104 are sequentially formed on an entire surface of the resulting substrate structure, thereby forming an insulation structure made of different kinds of the insulation layers.

The first insulation layer 103 includes a material selected from a group consisting of an oxide layer deposited through a PECVD method and an HDP oxide layer, a BPSG layer, a PSG layer, a BSG layer, a TEOS layer and a SOG layer. The second insulation layer 104 is made of a nitride layer which has a different etch selectivity from the first insulation layer 103, or an organic material-based insulation layer such as hydrogen silsesquioxane (HSQ) or silk.

Since it is necessary to remove only the second insulation layer 104 from the first insulation layer 103 and the second insulation layer 104 by a subsequent process, the insulation structure is formed by using materials having different etch properties.

Subsequently, to form a contact hole, a photoresist pattern 105 is formed on the second insulation layer 104.

Next, the second insulation layer 104 and the first insulation layer 103 are sequentially etched by using the photoresist pattern 105 as an etch mask, thereby forming a contact hole 106 exposing the cell contact plug 102.

The contact hole 106 includes a circle type or an ellipse type.

Next, a photoresist strip process is carried out, thereby removing the photoresist pattern 105. Afterwards, a cleaning process is performed.

Next, as shown in FIG. 7B, a conductive material such as polysilicon is filled into the contact hole 106, thereby providing a contact plug 107 electrically connected with the cell contact plug 102.

An upper portion of the contact plug 107 is planarized through a blanket-etch or a chemical mechanical polishing (CMP) process. At the same time, although not illustrated, the contact plug 107 is also isolated from other neighboring contact plugs 107. Also, the contact plug 107 is formed by using a material selected singly or in combination from a group consisting of a silicon layer using polysilicon and amorphous silicon, tungsten and TiN.

Next, as shown in FIG. 7C, only the second insulation layer 104 is selectively removed. Thus, the contact plug 107 has a projected shape. At this time, it is preferable to use a wet etching process to prevent the contact plug 107 from being damaged.

Accordingly, it is preferred that the second insulation layer 104 is made of a material having a higher etch ratio than that of the first insulation layer 103 when the wet etching process is performed.

Next, a barrier layer 108 is formed over the whole resulting profile. At this time, the barrier layer 108 is made of nitride-based material. Although a mis-alignment occurs during forming the contact plug 107, the barrier layer 108 can prevent a chemical damage on the first insulation layer 101, the bit line, and even on the cell contact plug 102 and the substrate 100 during a subsequent dip-out process.

Next, as shown in FIG. 7D, a sacrificial insulation layer 109 for forming a capacitor is formed on the barrier layer 108. The sacrificial insulation layer 109 is based on oxide and determines a height of the capacitor, which affects capacitance. Afterwards, a mask pattern 110 is formed to pattern the sacrificial insulation layer 109.

The sacrificial insulation layer 109 is etched by using the mask pattern 110 as an etch mask. That is, the etching process is stopped on the barrier layer 108 and then, the barrier layer 108 is removed. Thus, an opening 111 exposing a surface of the contact plug 107 is formed.

Next, the mask pattern 110 is removed and then, a cleaning process is performed to remove etch remnants.

The mask pattern 110 includes a single photoresist pattern, a structure of a photoresist pattern/an anti-reflective layer, a structure of a photoresist pattern/an anti-reflective layer/a sacrificial hard mask or a structure of a photoresist pattern/a sacrificial hard mask.

The sacrificial hard mask serves a role in complementing degradation in an etch barrier property of the photoresist pattern caused by high resolution. The sacrificial hard mask is formed by mainly using a material selected from a group consisting of polysilicon, tungsten and nitride.

Next, as shown in FIG. 7E, a conductive layer 112 is formed over the opening 111. Thus, the conductive layer 112 gets in contact with the contact plug 107. Herein, the conductive layer 112 is form forming the storage node of the capacitor.

A metal layer (not shown) acting as a barrier is formed before the conductive layer 112 for the storage node is formed. However, an explanation about the formation of the metal layer is omitted. The metal layer is formed by using one of TiSi₂, Ti, TiN and tungsten nitride (WNi₂).

Next, a photoresist layer is formed enough to bury the opening 111 and then, a blanket-etch or a CMP process is performed until a surface of the sacrificial insulation layer 109 is exposed, thereby providing an isolated and planarized storage node as shown in FIG. 6.

Subsequently, the storage node is made to be a cylinder type by removing the sacrificial insulation layer 109 through performing a full dip-out process.

Meanwhile, during performing the dip-out process, a partial dip-out process, instead of the full dip-out process, is carried out, thereby causing the sacrificial insulation layer 109 to remain. Thus, it is also possible to form a concave type storage node 112.

During performing the dip-out process, a chemical obtained by mixing hydrogen peroxide (H₂O₂) with one of BOE, HF and H2SO4 in a ratio of 1 to 4 is used.

Next, in order to recover a degraded property of the storage node due to the etching process, a thermal process can be performed. At this time, a cleaning process is shortly carried out by using the BOE solution before a dielectric layer is formed and thus, an additional process for removing impurities is followed.

Meanwhile, in case of forming the storage node through a meta-stable polysilicon (MPS) process, polysilicon is deposited and then, MPS is grown only on the inner side of the storage node through suitable conditions on a temperature and a pressure required for the growth of the MPS. Afterwards, the CMP process is performed.

Although not shown, the dielectric layer and a plate electrode are formed on the storage node, thereby completing a series of processes for forming the capacitor.

As described above, the present invention makes a contact plug for a storage node projected from a surface level of an insulation layer and covers the insulation layer and a portion of the contact plug for the storage node that are not contacted to the storage node with a nitride-based barrier layer. Thus, it is possible to form the storage node in a three-dimensional structure such as a cylinder type or a concave type, thereby securing an electric charge storage capacitance. It is also possible to prevent a bottom structure from being chemically damaged during a dip-out process with use of a barrier layer even if a mis-alignment occurs due to a lack of an over-lap margin.

As a result of the effects, it is further possible to improve yields of semiconductor devices.

The present application contains subject matter related to the Korean patent application No. KR 2004-0059533, filed in the Korean Patent Office on Jul. 29, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A semiconductor device, comprising:
an inter-layer insulation layer formed on a substrate;
a first plug contacted to the substrate by penetrating into the inter-layer insulation layer;
an insulation layer formed on the first plug;
a second plug contacted to the first plug by penetrating into the insulation layer and projected in an upward direction from a surface level of the insulation layer;
a barrier layer formed on the second plug and the insulation layer; and
a storage node formed on the second plug to be connected with the second plug through a portion where the barrier layer is removed.

2. The semiconductor device of claim 1, wherein the barrier layer includes a nitride-based insulation layer.

3. The semiconductor device of claim 1, wherein the insulation layer is made of a material selected from a group consisting of oxide obtained through employing a plasma enhanced chemical vapor deposition (PECVD) method, high density plasma (HDP) oxide and borophosphosilicate glass (BPSG).

4. The semiconductor device of claim 1, wherein the storage node is formed in one of a concave type and a cylinder type.

5. A method for forming a semiconductor device, comprising the steps of:
forming an inter-layer insulation layer on a substrate;
forming a first plug contacted to the substrate by penetrating into the inter-layer insulation layer;
sequentially forming a first insulation layer and a second insulation layer on the first plug;
selectively etching the first insulation layer and the second insulation layer to form a contact hole exposing the first plug;
forming a second plug contacted to the first plug through the contact hole and planarized at the same level as the second insulation layer;
removing the second insulation layer, thereby causing the second plug to be projected from a surface of the first insulation layer;
forming a barrier layer over the projected second plug;
forming a sacrificial insulation layer on the barrier layer;
selectively etching the sacrificial insulation layer and the barrier layer to form an opening exposing the second plug;
forming a conductive layer over the opening;
performing a planarization process until the sacrificial insulation layer is exposed, thereby forming an isolated storage node; and
selectively removing the sacrificial insulation layer through a dip-out process.

6. The method of claim 5, wherein the step of removing the second insulation layer is carried out through a wet etching process and the second insulation layer has a higher wet etch ratio than that of the first insulation layer.

7. The method of claim 6, wherein the first insulation layer includes a material selected from a group consisting of oxide obtained through a plasma enhanced chemical vapor deposition (PECVD) method, high density plasma (HDP) oxide, borophosphosilicate glass (BPSG), phosphosilicate glass (PSG), borosilicate glass (BSG), tetraethylorthosilicate (TEOS) and spin-on-glass (SOG).

8. The method of claim 7, wherein the second insulation layer includes one of a nitride-based insulation layer and an insulation layer based on an organic material.

9. The method of claim 5, wherein the barrier layer includes a nitride-based insulation layer.

10. The method of claim 5, wherein the step of selectively removing the sacrificial insulation layer employs a full dip-out process to form the storage node in a cylinder type.

11. The method of claim 5, wherein the step of selectively removing the sacrificial insulation layer employs a partial dip-out process to form the storage node in a concave type.
